(19) United States
(12) Patent Application Publication
(10) Pub. No.: US 2025/0149311 A1
(43) Pub. Date: May 8, 2025

(54) SUBSTRATE PROCESSING APPARATUS

(71) Applicant: Samsung Electronics Co., Ltd., Suwon-si (KR)

(72) Inventors: Junho IM, Suwon-si (KR); Younseon WANG, Suwon-si (KR); Keonwoo KIM, Suwon-si (KR); Youngjin NOH, Suwon-si (KR); Dougyong SUNG, Suwon-si (KR); Wonhee LEE, Suwon-si (KR); Sungwook JUNG, Suwon-si (KR)

(73) Assignee: Samsung Electronics Co., Ltd., Suwon-si (KR)

(21) Appl. No.: 18/762,910

(22) Filed: Jul. 3, 2024

(30) Foreign Application Priority Data
Nov. 3, 2023 (KR) 10-2023-0151032

(51) Int. Cl. H01J 37/32; C23C 16/458; H01L 21/683

(52) U.S. Cl. CPC H01J 37/32724; C23C 16/4586; H01L 21/6833; H01J 2237/2007

(57) ABSTRACT

A substrate processing apparatus may include a chucking member configured to support a substrate, a base plate configured to support the chucking member, a bonding layer located between the chucking member and the base plate, the bonding layer configured to adhere the chucking member to the base plate, a coating layer on an outer side surface of the bonding layer, and a bonding protective member surrounding an outer side surface of the coating layer, wherein the coating layer conformally covers the outer side surface of the bonding layer.

### CROSS-REFERENCE TO RELATED APPLICATION

This application is based on and claims priority under 35 U.S.C. § 119 to Korean Patent Application No. 10-2023-0151032, filed on Nov. 3, 2023, in the Korean Intellectual Property Office, the disclosure of which is incorporated by reference herein in its entirety.

### BACKGROUND

Inventive concepts relate to a substrate processing apparatus, for example to a substrate processing apparatus including a bonding layer configured to adhere, to a base plate, a chucking member configured to support a substrate, and methods of manufacture thereof.

A semiconductor device may be manufactured by forming a predetermined, or, alternatively, a desired, pattern on a substrate. When the predetermined or desired pattern is formed on the substrate, a plurality of processes, such as a deposition process, a photolithography process, and/or an etching process, may be performed by equipment used in a semiconductor manufacturing process.

### SUMMARY

Inventive concepts relate to a substrate processing apparatus by which a bonding layer configured to adhere a chucking member to a base plate may be protected from plasma and/or a reactive gas.

Technical objectives of inventive concepts are not limited to the above objectives; other objectives may become apparent to those of ordinary skill in the art based on the following descriptions.

According to some example embodiments of inventive concepts, a substrate processing apparatus may include a chucking member configured to support a substrate, a base plate configured to support the chucking member, a bonding layer between the chucking member and the base plate, the bonding layer configured to adhere the chucking member to the base plate, a coating layer on an outer side surface of the bonding layer, and a bonding protective member surrounding an outer side surface of the coating layer, wherein the coating layer conformally covers the outer side surface of the bonding layer.

According to some example embodiments of inventive concepts, a substrate processing apparatus may include a chucking member configured to support a substrate by electrostatic force, a base plate configured to support the chucking member, a first bonding layer in contact with the chucking member between the chucking member and the base plate, a first coating layer on an outer side surface of the first bonding layer, the first coating layer conformally covering the outer side surface of the first bonding layer in a groove region defined by a bottom surface of the chucking member, a top surface of the base plate and the outer side surface of the first bonding layer, and a bonding protective member surrounding an outer side surface of the first coating layer, wherein the base plate, the first bonding layer, and the chucking member include a pin hole extending in a vertical direction perpendicular to a top surface of the chucking member, and a second coating layer conformally covers an inner wall of the pin hole.

According to some example embodiments of inventive concepts, a substrate processing apparatus may include a housing, a shower head unit inside the housing, the shower head unit being configured to supply a process gas for processing a substrate in the housing, a substrate support unit installed under the shower head unit and configured to have the substrate seated thereon, and a plasma generating unit configured to generate plasma by using the process gas to process the substrate, wherein the substrate support unit includes a chucking member configured to support the substrate by electrostatic force, a base plate configured to support the chucking member, a bonding layer between the chucking member and the base plate, the bonding layer configured to adhere the chucking member to the base plate, a coating layer inside a groove region, the coating layer including metal oxide formed on the outer side surface of the bonding layer by using a deposition process, the groove region defined by a bottom surface of the chucking member, a top surface of the base plate, and an outer side surface of the bonding layer, and a bonding protective member surrounding an outer side surface of the coating layer, wherein the base plate, the bonding layer, and the chucking member include a pinhole extending in a vertical direction perpendicular to a top surface of the chucking member, and a second coating layer conformally covers the inner wall of the pin hole, the second coating layer including a metal oxide by the deposition process.

### BRIEF DESCRIPTION OF THE DRAWINGS

Example embodiments will be more clearly understood from the following detailed description taken in conjunction with the accompanying drawings in which:

FIG. 1 is a cross-sectional view of a structure of a substrate processing apparatus 100 according to an example embodiment;

FIG. 2 is an enlarged view of a substrate support unit configured to support a substrate;

FIG. 3 is an enlarged view of region “A” of FIG. 2;

FIGS. 4, 5, 6, 7, 8, 9, and 10 are enlarged views of substrate processing apparatuses according to example embodiments corresponding to region “A” of FIG. 3;

FIG. 11 is an enlarged view of a substrate support unit of a substrate processing apparatus according to an example embodiment;

FIG. 12 is an enlarged view of region “B” of FIG. 11; and

FIGS. 13 to 19 are cross-sectional views of a process sequence of a process of manufacturing a substrate processing apparatus.

### DETAILED DESCRIPTION

Example embodiments are described more fully hereinafter with reference to the accompanying drawings Inventive concepts may, however, be embodied in many different forms and should not be construed as limited to the example embodiments set forth herein. Rather, these example embodiments are provided so that the inventive concept will be thorough and complete, and will fully convey the scope of the inventive concept to those ordinarily skilled in the art.

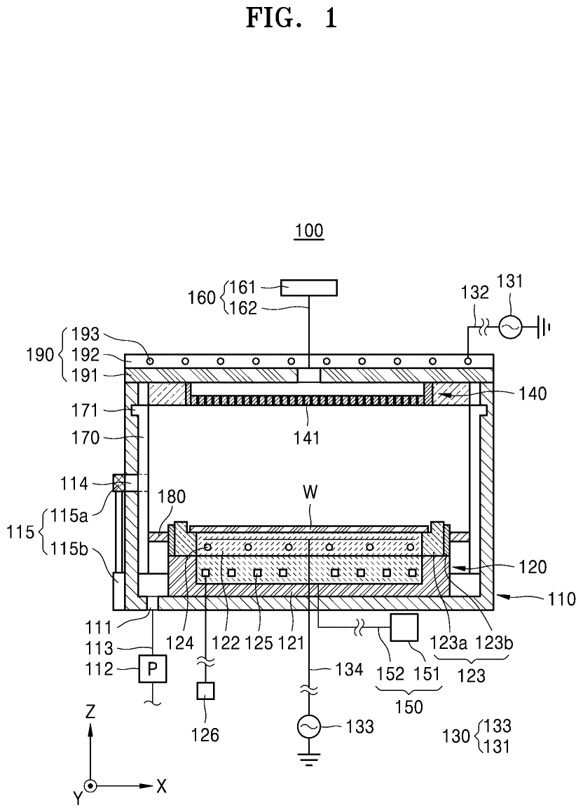

FIG. 1 is a cross-sectional view of a structure of a substrate processing apparatus 100 according to an some example embodiments.

Referring to FIG. 1, the substrate processing apparatus 100 may include a housing 110, a substrate support unit 120, a plasma generating unit 130, a shower head unit 140, a first gas supply unit 150, a second gas supply unit 160, a wall liner unit 170, a baffle unit 180, and an upper module 190.

The substrate processing apparatus 100 may be an apparatus configured to process a substrate W by using an etching process (e.g., a dry etching process) in a vacuum environment. The substrate processing apparatus 100 may process the substrate W by using, for example, a plasma process, but example embodiments are not limited thereto.

The housing 110 may provide a space in which the plasma process is performed. An exhaust hole 111 may be provided at a lower portion of the housing 110.

The exhaust hole 111 may be connected to an exhaust line 113 at which a pump 112 is mounted. The exhaust hole 111 may, for example, discharge a reaction byproduct generated during the plasma process and/or a residual gas remaining inside the housing 110 to the outside of the housing 110 through the exhaust line 113. For example, an inner space of the housing 110 may be depressurized to a desired (or, alternatively, predetermined) pressure.

An opening 114 may be formed in a sidewall of the housing 110. The opening 114 may function as a path through which the substrate W is loaded into and from the housing 110. The opening 114 may be configured to be opened and/or closed off by a door assembly 115.

The door assembly 115 may include an outer door 115a and a door driver 115b. The outer door 115a may be provided at an outer wall of the housing 110. The outer door 115a may be moved by the door driver 115b in, for example, a vertical direction (Z direction). The door driver 115b may operate using, for example, at least one of a motor, a hydraulic cylinder, or a pneumatic cylinder, but example embodiments are not limited thereto.

The substrate support unit 120 may be installed at, for example, an inner lower region of the housing 110. The substrate support unit 120 may support the substrate W by using, for example, electrostatic force. However, example embodiments are not limited thereto. The substrate support unit 120 may be capable of supporting the substrate W in various manners, such as, for example, a mechanical clamping process and a vacuum process.

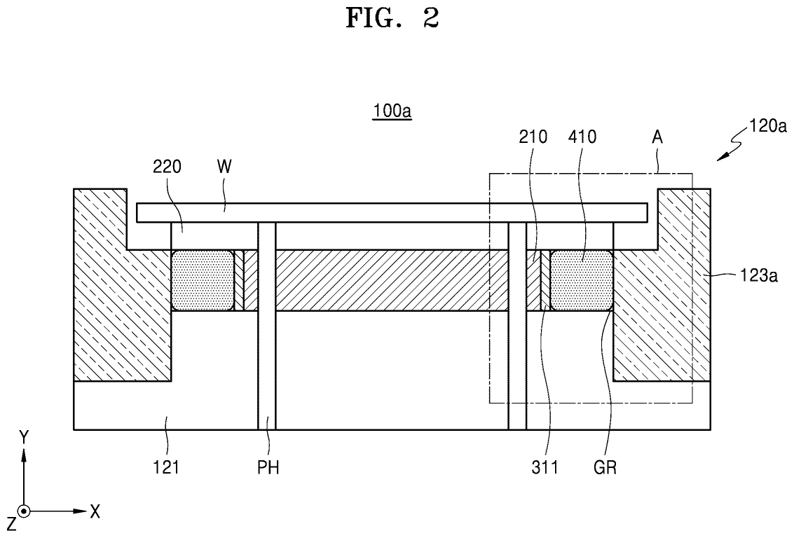

When the substrate support unit 120 supports the substrate W using electrostatic force, the substrate support unit 120 may be implemented as, for example, an electrostatic chuck (ESC) including a base plate 121 and a chucking member 220 (refer to FIG. 2).

The base plate 121 may support a chucking member. The base plate 121 may be formed using, for example, an aluminum (Al) component and provided as an Al base plate, but example embodiments are not limited thereto.

The chucking member 220 may support the substrate W seated thereon by using electrostatic force. The chucking member 220 may be formed using, for example, a ceramic component and provided as, for example, a ceramic plate or a ceramic puck. The chucking member 220 may be coupled to the base plate 121 and/or fixed onto the base plate 121, but example embodiments are not limited thereto.

A bonding layer (refer to 210 in FIG. 2) may be formed between the base plate 121 and the chucking member 220 formed on the base plate 121, and a bonding protective member may be installed outside the bonding layer 210 to protect the bonding layer 210. the bonding layer 210 and the bonding protective member are described in more detail below.

The chucking member 220 may be installed to be movable in the vertical direction (Z direction) inside the housing 110 by using, for example, a driving member (not shown). When the chucking member 220 is formed to be movable in the vertical direction (Z direction) as described above, the substrate W may be located in a region showing a relatively uniform plasma distribution.

A ring assembly 123 may surround an edge of the chucking member 220. The ring assembly 123 may be provided in a ring shape or ring-like shape to support an edge region of the substrate W. The ring assembly 123 may include, for example, a focus ring 123a and an insulating ring 123b.

The focus ring 123a may be formed inside the insulating ring 123b to surround the chucking member 220. The focus ring 123a may include, for example, a silicon material, and focus (for example, be configured to focus) plasma on the substrate W.

The insulating ring 123b may be formed outside the focus ring 123a to surround the focus ring 123a. The insulating ring 123b may include, for example, a quartz material, but example embodiments are not limited thereto.

The ring assembly 123 may further include an edge ring (not shown), which may be in close contact with an edge of the focus ring 123a. The edge ring may be formed to reduce or prevent damage to a side surface of the chucking member 220 from plasma.

The first gas supply unit 150 may supply a first gas to remove foreign materials remaining on, for example, the ring assembly 123 or on an edge portion of the chucking member 220. The first gas supply unit 150 may include a first gas supply source 151 and a first gas supply line 152.

The first gas supply source 151 may, for example, supply nitrogen (N₂) gas as the first gas to the substrate support unit 120. However, example embodiments are not limited thereto. The first gas supply source 151 may supply other or additional gases and/or detergents to the substrate support unit 120.

The first gas supply line 152 may be provided between the chucking member 220 and the ring assembly 123. The first gas supply line 152 may be, for example, connected between the chucking member 220 and the focus ring 123a, but example embodiments are not limited thereto.

The first gas supply line 152 may be provided inside the focus ring 123a and connected between the chucking member 220 and the focus ring 123a.

When an etching process is performed inside the housing 110, a heating member 124 and a cooling member 125 may be provided such that the substrate W is maintained at a process temperature. To this end, the heating member 124 may be provided as, for example, a heating wire, and the cooling member 125 may be provided as, for example, a cooling line through which a coolant flows.

The heating member 124 and the cooling member 125 may be installed inside the substrate support unit 120 such that the substrate W is maintained at the process temperature. As an example, the heating member 124 may be installed inside the chucking member 220, and the cooling member 125 may be installed inside the base plate 121, but example embodiments are not limited thereto.

Moreover, the cooling member 125 may receive a coolant from a cooling device 126. The cooling device 126 may be, for example, installed outside the housing 110, but example embodiments are not limited thereto.

The plasma generating unit 130 may generate plasma from a residual gas remaining in a discharge space. For example, the discharge space may to a space located over the substrate support unit 120 in the inner space of the housing 110.

The plasma generating unit 130 may generate plasma in the discharge space inside the housing 110 by using, for example, an inductively coupled plasma (ICP) source. In such a case, the plasma generating unit 130 may use, for example, an antenna unit 193 installed in the upper module 190 as an upper electrode and use the substrate support unit 120 as a lower electrode.

However, example embodiments of the plasma generating unit 130 are not limited to the above. For example, the plasma generating unit 130 may generate plasma in the discharge space inside the housing 110 by using, for example a (CCP; Capacitively Coupled Plasma (CCP) source. In such a case, the plasma generating unit 130 may use, for example, the shower head unit 140 as the upper electrode and use the substrate support unit 120 as the lower electrode.

The plasma generating unit 130 may include, for example, an upper electrode, a lower electrode, an upper power source 131, and a lower power source 133. The upper power source 131 may apply power to the upper electrode (e.g.,, the antenna unit 193). The upper power source 131 may be provided to control characteristics of plasma. The upper power source 131 may be provided to adjust, for example, ion bombardment energy, but example embodiments are not limited thereto.

Although one upper power source 131 is illustrated in FIG. 1, the upper power source 131 may be provided in plural in example embodiments. When the upper power source 131 is provided in plural, the substrate processing apparatus 100 may further include, for example, a first matching network (not shown) electrically connected to a plurality of upper power sources.

The first matching network may, for example, match frequency powers with different magnitudes, which are received from the respective upper power sources, and apply the matched frequency power to the antenna unit 193. A first impedance matching circuit (not shown) configured to perform impedance matching on a first transmission line 132 configured to connect the upper power source 131 to the antenna unit 193. The first impedance matching circuit may act as, for example, a lossless passive circuit such that electrical energy is effectively (or maximally) transmitted from the upper power source 131 to the antenna unit 193.

The lower power source 133 may, for example, apply power to the lower electrode (e.g.,., the substrate support unit 120). The lower power source 133 may serve as a plasma source configured to generate plasma or control characteristics of plasma along with the upper power source 131.

Although a single lower power source 133 is illustrated in FIG. 1, the lower power source 133 may be provided in plural in example embodiments like the upper power source 131. When the lower power source 133 is provided in the plural, the substrate processing apparatus 100 may further include a second matching network (not shown) electrically connected to a plurality of lower power sources.

The second matching network may, for example, match frequency powers with different magnitudes, which are received from the respective lower power sources, and apply the matched frequency power, to the substrate support unit 120. A second impedance matching circuit (not shown) configured to perform impedance matching may be on a second transmission line 134 configured to connect the lower power source 133 to the substrate support unit 120. Like the first impedance matching circuit, the second impedance matching circuit may act as, for example, a lossless passive circuit such that electrical energy is effectively (or maximally) transmitted from the lower power source 133 to the substrate support unit 120.

The shower head unit 140 may be installed to vertically face the substrate support unit 120 inside the housing 110. The shower head unit 140 may include a plurality of gas feeding holes 141 to spray gas into the housing 110. The shower head unit 140 may have a greater diameter than the substrate support unit 120. Moreover, the shower head unit 140 may be formed using, for example, at least one silicon component and/or metal component,.

The second gas supply unit 160 may supply a process gas (a second gas) through the shower head unit 140 into the housing 110. The second gas supply unit 160 may include a second gas supply source 161 and a second gas supply line 162.

The second gas supply source 161 may supply an etching gas used to process the substrate W, for example as the process gas to the substrate support unit 120. The second gas supply source 161 may supply a gas containing, for example, a fluorine component (e.g., SF₆ and CF₄) as the etching gas, but example embodiments are not limited thereto. The second gas supply source 161 may be provided in singular and supply the etching gas to the shower head unit 140. However, example embodiments are not limited thereto The second gas supply source 161 may be provided in plural and supply the process gas to the shower head unit 140.

The second gas supply line 162 may connect the second gas supply source 161 to the shower head unit 140. The second gas supply line 162 may transfer the process gas, which may be supplied by the second gas supply source 161, to the shower head unit 140, and accordingly, the etching gas may flow into the housing 110.

When the shower head unit 140 is, for example, divided into a center zone, a middle zone, and an edge zone, the second gas supply unit 160 may further include, for example, a gas distributor (not shown) and a gas distribution line (not shown) to supply the process gas into each of the center zone, the middle zone, and the edge zone of the shower head unit 140.

The gas distributor may distribute the process gas supplied from the second gas supply source 161 to each of the center zone, the middle zone, and the edge zone of the shower head unit 140. The gas distributor may be connected to the second gas supply source 161 through the second gas supply line 162.

The gas distribution line may connect the gas distributor to each of the center zone, the middle zone, and the edge zone of the shower head unit 140. The process gas distributed by the gas distributor may be transferred through the gas distribution line to each of the center zone, the middle zone, and the edge zone of the shower head unit 140.

The second gas supply unit 160 may further include a third gas supply source (not shown) configured to supply a deposition gas to the shower head unit 140.

The third gas supply source may supply the deposition gas to the shower head unit 140 to protect a side surface of the substrate W and enable anisotropic etching. The third gas supply source may supply a gas, such as, for example, C₄F₈ and C₂F₄, to the deposition gas, but example embodiments are not limited thereto.

The wall liner unit 170 may protect an inner side surface of the housing 110 from, for example, arc discharge, which occurs during a process of exciting the process gas, and impurities generated during a substrate processing process. The wall liner unit 170 may be provided in, for example, a cylindrical or cylinder-like shape of which upper and lower portions are open inside the housing 110, but example embodiments are not limited thereto.

The wall liner unit 170 may be adjacent to an inner sidewall of the housing 110. A support ring 171 may be provided at an upper portion of the wall liner unit 170. The support ring 171 may protrude in an outward direction (i.e., X direction) from the upper portion of the wall liner unit 170 and be placed on an upper end of the housing 110 to support the wall liner unit 170.

The baffle unit 180 may exhaust, for example, process by-products of plasma and/or unreacted gases. The baffle unit 180 may be between the inner sidewall of the housing 110 and the substrate support unit 120. The baffle unit 180 may be provided, for example, in an annular ring shape and include a plurality of through holes penetrated in a vertical direction (Z direction). The baffle unit 180 may control the flow of the process gas depending on the number and shape of through holes.

The upper module 190 may be installed to cover an open upper portion of the housing 110. The upper module 190 may include a window member 191, an antenna member 192, and an antenna unit 193.

The window member 191 may be formed to cover an upper portion of the housing 110 to seal the inner space of the housing 110. The window member 191 may be provided in the form of a plate (e.g., a disk) and formed using an insulating material (e.g., alumina (Al₂O₃)). The window member 191 may include a dielectric window. The window member 191 may include a through hole into which the second gas supply line 162 may be inserted. A coating film may be formed on a surface of the window member 191 to inhibit particles from being generated when a plasma process is performed inside the housing 110.

The antenna member 192 may be installed on the window member 191 and provide a space with a desired (or, alternatively, predetermined) size such that the antenna unit 193 is inside the antenna member 192. The antenna member 192 may be formed in, for example, a cylindrical shape with an open lower portion and have a diameter corresponding to the housing 110, but example embodiments are not limited thereto. The antenna member 192 may be detachably provided on the window member 191.

The antenna unit 193 may function as, for example, an upper electrode, and a coil provided to form a closed loop may be mounted on the antenna unit 193. The antenna unit 193 may generate a magnetic field and an electrical field inside the housing 110, based on power supplied from the upper power source 131, and generate plasma by exciting gas that is introduced into the housing 110 through the shower head unit 140. A coil of, for example, a planar spiral type may be mounted on the antenna unit 193. However, example embodiments are not limited thereto. A structure or size of the coil may be variously modified by one ordinarily skilled in the art.

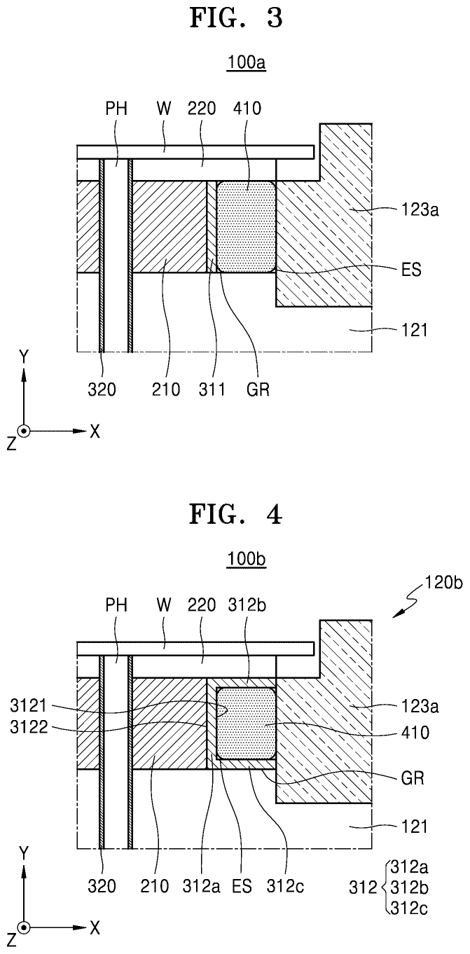

FIG. 2 is an enlarged view of a substrate support unit 120a configured to support a substrate, and FIG. 3 is an enlarged view of region A of FIG. 2. The substrate support unit 120 is described below with reference to FIGS. 2 and 3.

According to some example embodiments, a substrate processing apparatus 100a may include a first coating layer 311 on an outer side surface of the bonding layer 210 and a bonding protective member 410 surrounding an outer side surface of the first coating layer 311.

The bonding layer 210 may be configured to bring the chucking member 220 into contact with the base plate 121. The bonding layer 210 may be formed using, for example, a silicone component. However, example embodiments are not limited thereto. Additionally, or alternatively to the silicone component, the bonding layer 210 may be formed using other adhesive components that may effectively adhere the base plate 121 to the chucking member 220.

The bonding layer 210 may be formed to have an area less than an upper area of the base plate 121 between the base plate 121 and the chucking member 220. Also, the bonding layer 210 may be formed to have an area less than a lower area of the chucking member 220 between the base plate 121 and the chucking member 220. The bonding layer 210 may be formed in a central region between the base plate 121 and the chucking member 220.

A region surrounded (for example, defined by or at least partially defined) by a bottom surface of the chucking member 220, the outer side surface of the bonding layer 210, and a top surface of the base plate 121 may be defined as a groove region GR. The groove region GR may have a recessed shape when the substrate support unit 120a is viewed from the outside. In a cross-sectional view perpendicular to a top surface of the chucking member 220, the groove region GR may have a shape the same as, substantially the same as, or similar to the letter “U.”

According to some example embodiments, the first coating layer 311 may conformally cover the outer side surface of the bonding layer 210 inside the groove region GR. A thickness of the first coating layer 311 may be, for example, less than a thickness of the bonding layer 210 or a thickness of the bonding protective member 410 described below. The thickness of the first coating layer 311 may be in a range of, for example, about 100 nm to about 10 μm. When the thickness of the first coating layer 311 is, for example, greater than 10 μm, manufacturing cost for forming the first coating layer 311 may be excessive. When the thickness of the first coating layer 311 is less than, for example, 100 nm, the first coating layer 311 may not properly protect the bonding layer 210.

In the cross-sectional view perpendicular to the top surface of the chucking member 220, the first coating layer 311 may have the form of or similar to a square plate. In such a case, a top surface of the first coating layer 311 may be in contact with the chucking member 220, and a bottom surface of the first coating layer 311 may be in contact with the base plate 121.

The bonding protective member 410 may be configured to protect the bonding layer 210. The bonding protective member 410 may surround a side surface of the bonding layer 210 between the base plate 121 and the chucking member 220. However, in some example embodiments the bonding protective member 410 may not be in direct contact with the bonding layer 210, and the first coating layer 311 may be between the bonding protective member 410 and the bonding layer 210, but example embodiments are not limited thereto. The bonding protective member 410 may include, for example, a material having excellent etching resistance. The bonding protective member 410 may include, for example, a Teflon material, but example embodiments are not limited thereto.

Because the top surface of the base plate 121 has a platform, a lower end portion of the groove region GR may be, for example, coplanar with a top surface of the base plate 121, which may be in contact with the bonding layer 210. In such a case, a vertical length of the first coating layer 311 in the vertical direction (Z direction) may be equal or substantially equal to each of a vertical length of the bonding protective member 410 and a vertical length of the bonding layer 210. When the lower end portion of the groove region GR (e.g., a top surface of the base plate 121, which may not in contact with the bonding layer 210) is coplanar with the top surface of the base plate 121 in contact with the bonding layer 210, because the first coating layer 311 may be deposited only on the outer side surface of the bonding layer 210, the first coating layer 311 may be formed to a relatively uniform thickness during a deposition process, but example embodiments are not limited thereto.

According to some example embodiments, a separation space ES may be between (for example, defined or at least partially defined by or between) the bonding layer 210 and the bonding protective member 410. In the cross-sectional view perpendicular to a top surface of the chucking member 220, a corner portion of a cross-section of the bonding protective member 410 may have, for example, a fillet form or fillet-like form. Accordingly, because the corner portion of the cross-section of the bonding protective member 410 is not in contact with the bonding layer 210, the separation space ES may be between the corner portion and the bonding layer 210. The bonding protective member 410 shown in FIGS. 3 to 5 may be formed using, for example, a flexible material or an elastic material and may be a member fastened to the groove region GR, but example embodiments are not limited thereto. The bonding protective member 410 may, for example, be a separate member having a certain shape and may be fastened to the groove region GR.

According to some example embodiments, the first coating layer 311 may be deposited on an outer sidewall of the bonding layer 210 by using, for example, a deposition process. The first coating layer 311 may include, for example, metal oxide. For example, the first coating layer 311 may include Al₂O₃, for example, Y₂O₃, yttrium aluminum garnet (YAG), ZrO₂, TiO₂, or a combination thereof. However, material(s) that may be included in the first coating layer 311 is not limited to the materials described above.

According to some example embodiments, during a plasma process, the bonding layer 210 may be primarily protected by the bonding protective member 410 from gas or plasma outside the substrate support unit 120a and secondarily protected by the first coating layer 311.

The bonding layer 210 may be damaged by, for example, a target material accelerated in a sputtering process during the plasma process. The bonding protective member 410 may serve as, for example, a barrier to hinder or prevent the accelerated target material from reaching the bonding layer 210. The bonding protective member 410 may have a greater thickness than the first coating layer 311 in a lateral direction. The target material accelerated in the plasma process may have high energy and may damage or at least partially damage an outer side surface of the bonding protective member 410. However, due to the relatively great thickness of the bonding protective member 410, the accelerated target material may be hindered in, or prevented from, reaching the first coating layer 311. The bonding protective member 410 of which the outer side surface has been damaged by the accelerated target material may be detached from the groove region GR. Accordingly, a new bonding protective member 410 may be, for example, installed again inside the groove region GR.

A separation space ES may be (for example, defined or at least partially defined) between the first coating layer 311 and the bonding protective member 410, and a reactive gas used in the plasma process may penetrate into the first coating layer 311 through the separation space ES. Because the reactive gas may have a smaller molecular size than the target material, the reactive gas may penetrate the bonding protective member 410 and reach the first coating layer 311 inside the groove region GR. The first coating layer 311 may serve as a barrier to hinder or prevent the reactive gas from reaching the bonding layer 210. Although the first coating layer 311 may have a relatively small thickness, the first coating layer 311 may be conformally formed using a deposition process to at least partially cover or completely cover the outer side surface of the bonding layer 211.

According to some example embodiments, pin holes PH may be formed to pass through the base plate 121, the bonding layer 210, and the chucking member 220 in the vertical direction (Z direction). For example, a lengthwise direction of the pin holes PH may correspond to the vertical direction (Z direction). Each of the pin holes PH may be formed to extend to a lower end of the base plate 121. A lift pin (not shown) may be inserted into each of the pin holes PH. The lift pin may be movable in the vertical direction (Z direction) inside the pin hole PH. The lift pin may support the substrate W to have the substrate W seated on the chucking member 220.

A second coating layer 320 may be formed inside the pin hole PH. The second coating layer 320 may have a conformal thickness and be formed in a lengthwise direction (e.g., the vertical direction (Z direction)) along an inner wall of the pin hole PH. In such a case, the bonding layer 210 extending in a lateral direction (e.g., a first direction (X direction) or a second direction (Y direction)) may be exposed at an upper end of the pin hole PH. The second coating layer 320 may be in contact with the bonding layer 210 exposed through the pin hole PH.

For example, a diameter of the pin hole PH may be in a range of about 0.1 mm to about 1 mm, and the second coating layer 320 may be formed to have a thickness much less than the diameter of the pin hole PH, but example embodiments are not limited thereto. In such case, the first coating layer 311 and the second coating layer 320 may be formed at the same time. The second coating layer 32 may have a thickness less than the thickness of the second coating layer 320 according to a size of a space into which a reactive gas flows or a deposition temperature.

The second coating layer 320 may hinder or prevent plasma from penetrating between the pin hole PH and the lift pin driven through the pin hole PH, thereby mitigating or precluding the occurrence of sputtering. That is, the second coating layer 310 may act as a barrier to hinder or prevent the reactive gas that may flow into the pin hole PH from reaching the bonding layer 210. Like the first coating layer 311, the second coating layer 320 may protect the bonding layer 210 from the reactive gas.

FIGS. 4, 5, 6, 7, 8, 9, and 10 are enlarged views of substrate processing apparatuses according to example embodiments, which correspond to region A of FIG. 3.

A substrate processing apparatus 100b shown in FIG. 4 may the same or substantially be the same as the substrate processing apparatus 100a shown in FIG. 3 except that a shape of a first coating layer 312 is different from the first coating layer 311 shown in FIG. 3. Thus, descriptions of the same components as in FIG. 3 are omitted or briefly presented.

Referring to FIG. 4, the substrate processing apparatus 100b may include the first coating layer 312 on an outer side surface of a bonding layer 210 inside a groove region GR and a bonding protective member 410 surrounding an outer side surface of the first coating layer 312.

According to some example embodiments, in a cross-sectional view perpendicular to a top surface of a chucking member 220, the first coating layer 312 may have a U or U-like cross-sectional shape. The first coating layer 312 may include a first portion 312a, a second portion 312b, and a third portion 312c. The first portion 312a may be in contact with the outer side surface of the bonding layer 210 and extend in a vertical direction (Z direction). The second portion 312b may integrally extend from the first portion 312a in a lateral direction (e.g., a first direction (X direction) or a second direction (Y direction)) and be in contact with the chucking member 220. The third portion 312c may integrally extend from the first portion 312a in a lateral direction (e.g., the first direction (X direction) or the second direction (Y direction)) and be in contact with a base plate 121. In this case, the second portion 312b and the third portion 312c may face each other.

According to some example embodiments, the bonding protective member 410 may be surrounded (for example, at least partially surrounded) by the first portion 312a, the second portion 312b, and the third portion 312c inside the groove region GR. When metal oxide is deposited not only on the outer side surface of the bonding layer 210 but also on the top surface of the base plate 121 and a bottom surface of the chucking member 220 during the formation of the first coating layer 312, the second portion 312b and the third portion 312c of the first coating layer 312 may be formed.

A first surface 3121 of the first coating layer 312 may have a U or U-like shape and be in contact with the bonding protective member 410. A second surface 3122 of the first coating layer 312, which is opposite to the first surface 3121, may be in contact with the outer side surface of the bonding layer 210, the bottom surface of the chucking member 220, and the top surface of the base plate 121.

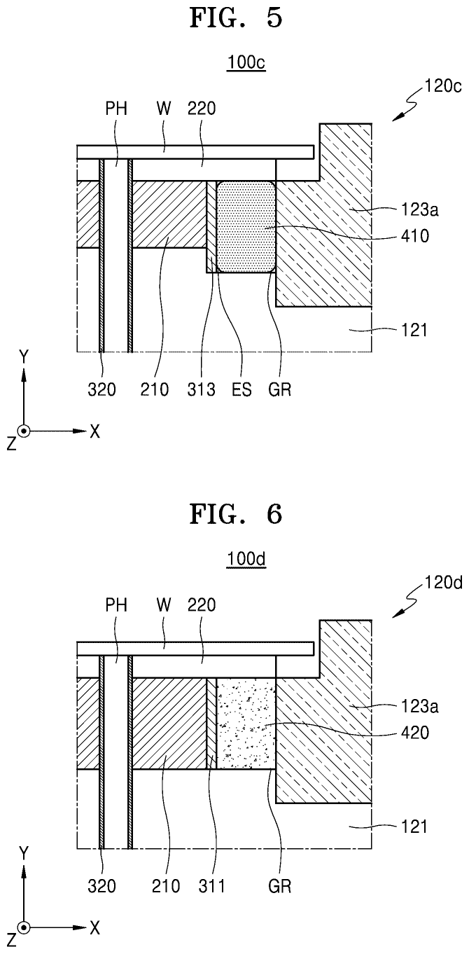

A substrate processing apparatus 100c shown in FIG. 5 may be the same as or substantially be the same as the substrate processing apparatus 100a shown in FIG. 3 except that a vertical length of a bonding layer 210 is different from the vertical length of the bonding layer 210 shown in FIG. 3. Thus, descriptions of the same components as in FIG. 3 are omitted or briefly presented.

Referring to FIG. 5, the substrate processing apparatus 100c may include a first coating layer 313 on an outer side surface of the bonding layer 210 inside a groove region GR and a bonding protective member 410 surrounding an outer side surface of the first coating layer 313. In this case, a vertical length of the bonding layer 210 in the vertical direction (Z direction) may be less than each of a vertical length of the first coating layer 313 and a vertical length of the bonding protective member 410. Because the vertical length of the bonding layer 210 is less than each of the vertical length of the first coating layer 313 and the vertical length of the bonding protective member 410, the bonding layer 210 may be stably protected from a reactive gas and an accelerated target material.

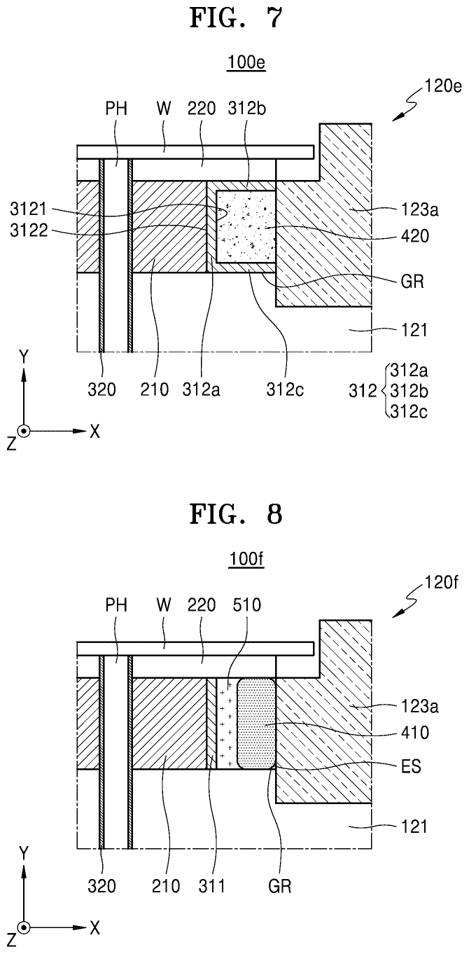

Substrate processing apparatuses 100d and 100e shown in FIGS. 6 and 7 may be the same as or substantially be the same as the substrate processing apparatuses 100a and 100b shown in FIGS. 3 and 4 except that a bonding protective member 420 is different from each of the bonding protective members 410 shown in FIGS. 3 and 4. Thus, descriptions of the same components as in FIG. 3 are omitted or briefly presented.

Referring to FIGS. 6 and 7, the substrate processing apparatus 100d or 100e may include a first coating layer 311 or 312 on an outer side surface of a bonding layer 210 inside a groove region GR and a bonding protective member 420 surrounding an outer side surface of the first coating layer 311 or 312.

Unlike the bonding protective member 410 shown in FIGS. 3 and 4, the bonding protective member 420 shown in FIGS. 6 and 7 may not be fastened onto the first coating layer 311 or 312 inside the groove region GR but be formed on the first coating layer 311 or 312 using a deposition process. Accordingly, unlike the bonding protective member 410 shown in FIGS. 2 to 5, the bonding protective member 420 may completely cover the outer side surface of the first coating layers 311 or 312. Unlike the bonding protective member 410 shown in FIGS. 3 and 4, a separation space may not, for example, be formed between the bonding protective member 420 and the first coating layer 311 or 312 or between the bonding protective member 420 and the focus ring 123a.

The bonding protective member 420 may include, for example, a polymer material deposited on the first coating layers 311 or 312. The bonding protective member 420 may be formed using a material having, for example, thermal stability and a low thermal expansion rate. For example, the bonding protective member 420 may include polyimide (PI), (poly) norbornene, highly heat-resistant polyester (PET), epoxy, or urethane. Additionally or alternatively, the bonding protective member 420 may include a copolymer. For example, the bonding protective member 420 may be formed using a polymer of polymethyl methacrylate (PMMA) and special PMMA, a copolymer of polycarbonate (PC) and PI, a copolymer of PMMA and PI, or a copolymer of urethane, but example embodiments are not limited thereto. Alternatively, the bonding protective member 420 may include Teflon, but example embodiments are not limited thereto.

A substrate processing apparatus 100f shown in FIG. 8 may be the same as substantially be the same as the substrate processing apparatus 100a shown in FIG. 3 except that a sealing member 510 is between the first coating layer 311 and the bonding protective member 410. Thus, descriptions of the same components as in FIG. 3 are omitted or briefly presented.

Referring to FIG. 8, the substrate processing apparatus 100f may further include the sealing member 510 between the first coating layer 311 and the bonding protective member 410 inside the groove region GR.

According to some example embodiments, the sealing member 510 may prevent, or reduce the chance of, a separation space ES from occurring between the first coating layer 311 and one side surface of the bonding protective member 410, which faces the first coating layer 311. In a cross-sectional view perpendicular to a top surface of the chucking member 220, a top portion and a bottom portion of the sealing member 510 may protrude toward the bonding protective member 410. Thus, while the top portion and the bottom surface of the sealing member 510 are protruding toward the bonding protective member 410, occurrence of a separation space between the sealing member 510 and the bonding protective member 410 may be reduced or prevented. For example, the bonding protective member 410 may be formed, for example, using a polymer of PMMA and special PMMA, a copolymer of PC and PI, a copolymer of PMMA and PI, or a copolymer of urethane, but example embodiments are not limited thereto. For example,, the bonding protective member 410 may additionally or alternatively include Teflon.

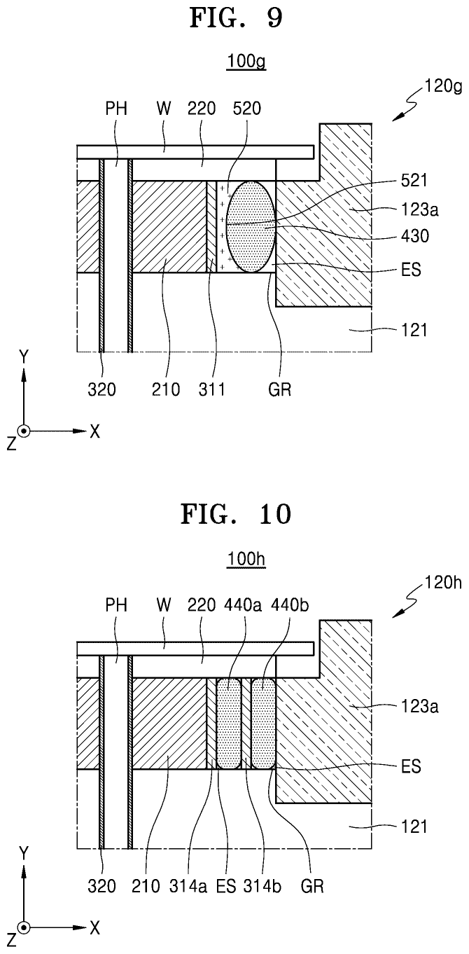

A substrate processing apparatus 100g shown in FIG. 9 may the same or substantially be the same as the substrate processing apparatus 100f shown in FIG. 8 except for shapes of a sealing member 520 and a bonding protective member 430. Thus, descriptions of the same components as in FIG. 8 are omitted or briefly presented.

Referring to FIG. 9, in a cross-sectional view perpendicular to a top surface of a chucking member 220, the bonding protective member 430 may have an elliptical shape. Accordingly, the bonding protective member 430 shown in FIG. 9 may have a more curved corner than the bonding protective member 430 shown in FIG. 8.

According to some example embodiments, the sealing member 520 may reduce or prevent the occurrence of a separation space ES between the first coating layer 311 and one side surface of the bonding protective member 430, which faces the first coating layer 311. In a cross-sectional view perpendicular to the top surface of the chucking member 220, a top portion and a bottom portion of the sealing member 520 may protrude toward the bonding protective member 430. Thus, while the top portion and the bottom portion of the sealing member 520 are protruding toward the bonding protective member 430, occurrence a separation space between the sealing member 520 and the bonding protective member 430 may be reduced or prevented. Unlike the sealing member 520 shown in FIG. 8, an outer side surface of the sealing member 510 shown in FIG. 9 may have a concave shape.

Also, the separation space ES between the sealing member 520 and the focus ring 123a in FIG. 9 may be greater in area (and/or volume) than the separation space ES between the sealing member 510 and the focus ring 123a in FIG. 8.

A substrate processing apparatus 100h shown in FIG. 10 may the same as or substantially be the same as the substrate processing apparatus 100a shown in FIG. 3 except that first coating layers 314a and 314b and bonding protective members 440a and 440b are configured in two stages. Thus, descriptions of the same components as in FIG. 3 are omitted or briefly presented.

Referring to FIG. 10, a pair of first coating layers 314a and 314b may be apart from each other in a lateral direction (e.g., a first direction (X direction) or a second direction (Y direction)). Of the pair of first coating layers 314a and 314b, the first coating layer 314a located on an inner side (i.e., on a side closer to the bonding layer 210) may be in contact with an outer side surface of the bonding layer 210. Of the pair of first coating layers 314a and 314b, the first coating layer 314b located on an outer side (i.e., on a side farther from the bonding layer 210) may be between a pair of bonding protective members 440a and 440b.

Of the pair of bonding protective members 440a and 440b, the bonding protective member 440a located on an inner side may be between the pair of first coating layers 314a and 314b. Of the pair of bonding protective members 440a and 440b, the bonding protective member 440b located on an outer side may be in contact with an inner side surface of the focus ring 123a.

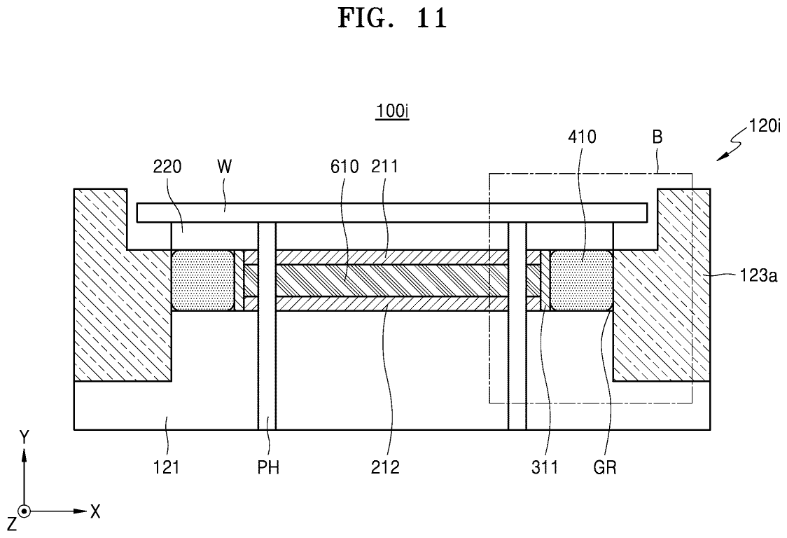

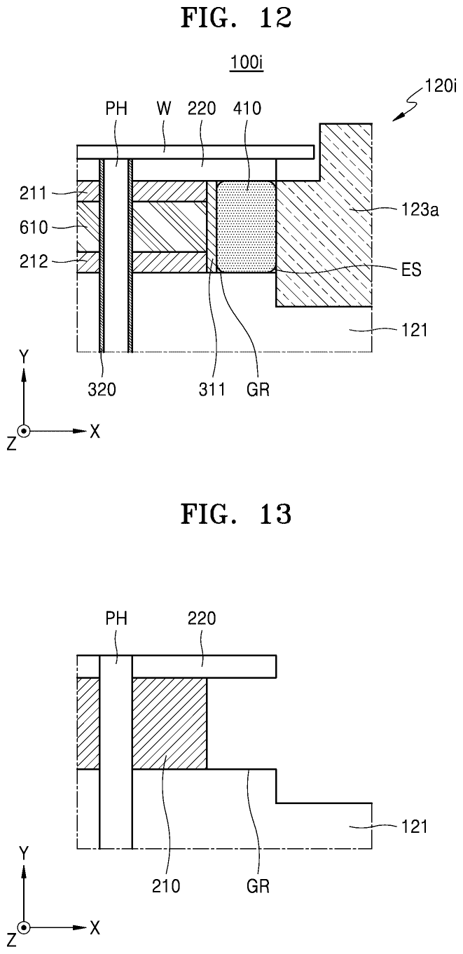

FIG. 11 is an enlarged view of a substrate support unit 120 of a substrate processing apparatus 100i according to some example embodiments. FIG. 12 is an enlarged view of region B of FIG. 11.

The substrate processing apparatus 100i shown in FIGS. 11 and 12 may be the same or substantially be the same as the substrate processing apparatus 100a shown in FIGS. 2 and 3 except that the substrate processing apparatus 100i further includes a heating plate 610. Thus, descriptions of the same components as in FIGS. 2 and 3 are omitted or briefly presented.

The substrate processing apparatus 100i may include a first bonding layer 211 in contact with a bottom surface of a chucking member 220 and a second bonding layer 212 in contact with a top surface of a base plate 121. In addition, the substrate processing apparatus 100i may further include the heating plate 610 between the first bonding layer 211 and the second bonding layer 212. The heating plate 610 may include a metal or a ceramic material, and a heater, such as a heating film, may be at the bottom of the heating plate 610.

A side surface of the first bonding layer 211, a side surface of the second bonding layer 212, and a side surface of the heating plate 610 may be arranged in a vertical direction (Z direction). A groove region GR may be defined or at least partially in a space among a side surface of the first bonding layer 211, a side surface of the second bonding layer 212, a side surface of the heating plate 610, the bottom surface of the chucking member 220, and the top surface of the base plate 121.

The first coating layer 311 may be in contact with the side surface of the first bonding layer 211, the side surface of the second bonding layer 212, and the side surface of the heating plate 610 inside the groove region GR. The first coating layer 311 may be formed to a conformal thickness on the side surface of the first bonding layer 211, the side surface of the second bonding layer 212, and the side surface of the heating plate 610.

A second coating layer 320 may cover an inner side surface of the chucking member 220, an inner side surface of the first bonding layer 211, an inner side surface of the heating plate 610, an inner side surface of the second bonding layer 212, and an inner side surface of the base plate 121 inside a pin hole PH.

FIGS. 13 to 19 are cross-sectional views of a process sequence of a process of manufacturing a substrate processing apparatus.

Referring to FIG. 13, a base plate 121, a chucking member 220, and a bonding layer 210 may be provided. The chucking member 220 may be on the base plate 121. The bonding layer 210 may bring the chucking member 220 into contact with the base plate 121. In this case, a groove region GR may be defined (or at least partially defined) by a top surface of the base plate 121, a bottom surface of the chucking member 220, and a side surface of the bonding layer 210. In addition, a pin hole PH may be formed to pass through the chucking member 220, the bonding layer 210, and the base plate 121 in a vertical direction (Z direction).

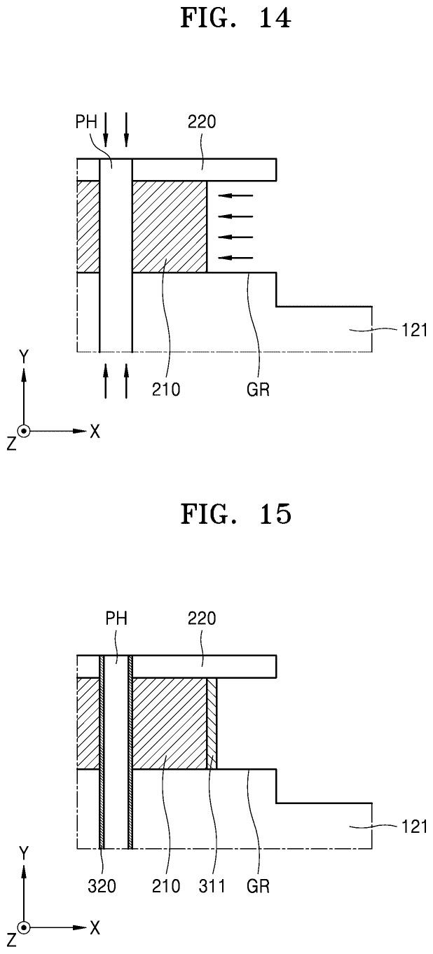

Referring to FIGS. 14 and 15, a deposition process may be performed on the groove region GR and the pin hole PH. The deposition process may include, for example, atomic layer deposition (ALD), chemical vapor deposition (CVD),physical vapor deposition (PVD), or combination thereof.

By depositing metal oxide using the deposition process, a first coating layer 311 may be formed on the sidewall of the bonding layer 210, and a second coating layer 320 may be formed on an inner side surface at least partially defining the pin hole PH. The first coating layer 311 may conformally cover an outer side surface of the bonding layer 210, and the second coating layer 320 may conformally cover an inner sidewall surface of the pin hole PH.

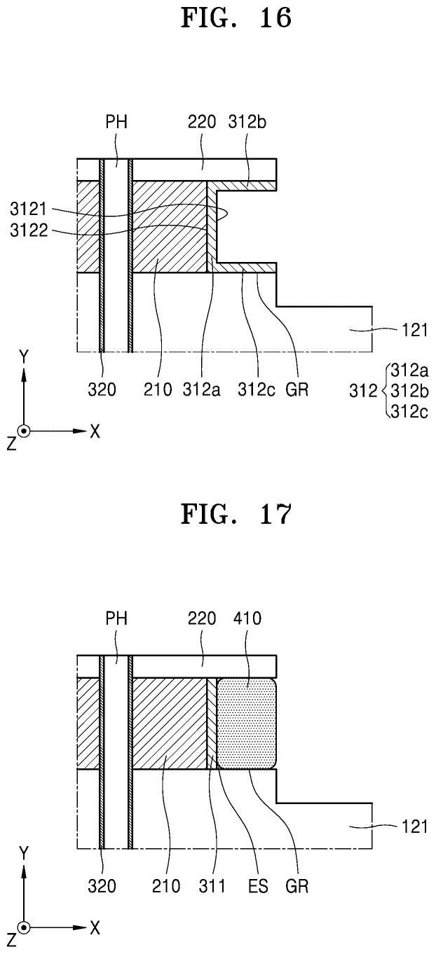

FIG. 16 illustrates a first coating layer 312 formed according to some example embodiments. During a deposition process, metal oxide may be formed not only on an outer side surface of a bonding layer 210, but also on a top surface of the base plate 121 and a bottom surface of a chucking member 220.

According to some example embodiments, in a cross-sectional perpendicular to a top surface of the chucking member 220, the first coating layer 312 may have a U or U-like cross-sectional shape. The first coating layer 312 may include a first portion 312a, a second portion 312b, and a third portion 312c. The first portion 312a may be in contact with the outer side surface of the bonding layer 210 and extend in a vertical direction (Z direction). The second portion 312b may integrally extend from the first portion 312a in a lateral direction (e.g., a first direction (X direction) or a second direction (Y direction)) and be in contact with the chucking member 220. The third portion 312c may integrally extend from the first portion 312a in a lateral direction (e.g., the first direction (X direction) or the second direction (Y direction)) and be in contact with the base plate 121. In this case, the second portion 312b and the third portion 312c may face each other. A first surface 3121 of the first coating layer 312 may have a U or U-like shape, and a second surface 3122 of the first coating layer 312 may have a flat or substantially flat shape.

Referring to FIG. 17, inside the groove region GR, a bonding protective member 410 may be fastened onto an outer side surface of a first coating layer 311. In such a case, the bonding protective member 410 may be in contact with the outer side surface of the first coating layer 311, and a separation space ES may be formed between the bonding protective member 410 and the first coating layer 311. The separation space ES may be formed (for example defined or at least partially defined) between a corner portion of the bonding protective member 410 and the first coating layer 311.

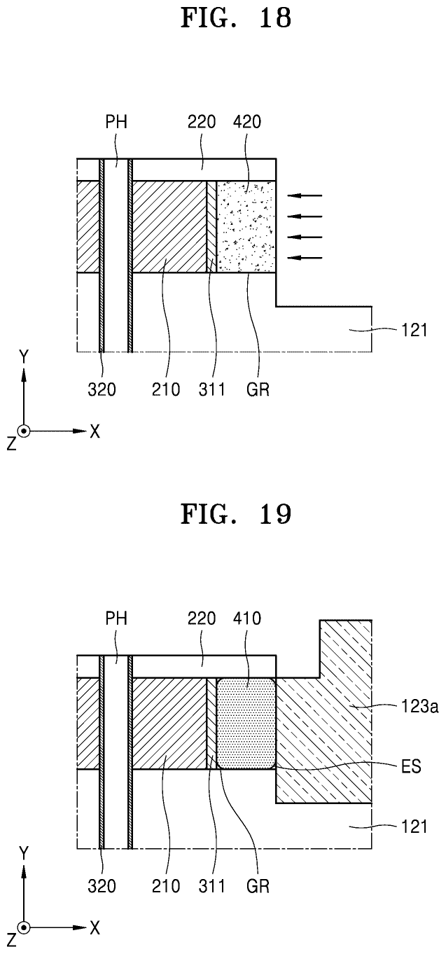

FIG. 18 illustrates a bonding protective member 420 formed according to some example embodiments. Referring to FIG. 18, in a groove region GR, a bonding protective member 420 may be formed by using a deposition process on an outer side surface of a first coating layer 311. In such a case, the deposition process may include ALD, CVD, PVD, or combination thereof. In such a case, the bonding protective member 420 may be in contact with the outer side surface of the first coating layer 311, and there may be no separation space between the bonding protective member 420 and the first coating layer 311.

Referring to FIG. 19, the bonding protective member 410 may be fastened onto the outer side surface of the first coating layer 311. Thereafter, a focus ring 123a may be fastened onto an outer side surface of the bonding protective member 410. In such case, the focus ring 123a may be completely in contact with the outer side surface of the bonding protective member 410 and partially in contact with a bottom surface of the chucking member 220.

While inventive concepts has been particularly shown and described with reference to embodiments thereof, it will be understood by one of ordinary skill in the art that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A substrate processing apparatus, comprising:
a chucking member configured to support a substrate;
a base plate configured to support the chucking member;
a bonding layer between the chucking member and the base plate, the bonding layer configured to adhere the chucking member to the base plate;
a coating layer on an outer side surface of the bonding layer; and
a bonding protective member surrounding an outer side surface of the coating layer,
wherein the coating layer conformally covers the outer side surface of the bonding layer.

2. The substrate processing apparatus of claim 1, wherein a vertical length of the coating layer is equal to
a vertical length of the bonding protective member, and
a vertical length of the bonding layer.

3. The substrate processing apparatus of claim 1, wherein
the coating layer has a U-shape when viewed in a cross-sectional view perpendicular to a top surface of the chucking member,
a first surface of the coating layer covers the bonding protective member, and
a second surface of the coating layer covers the bonding layer, the chucking member, and the base plate, the second surface of the coating layer opposing the first surface of the coating layer.

4. The substrate processing apparatus of claim 1, wherein the bonding protective member has a fillet-type corner when viewed in a cross-sectional view perpendicular to a top surface of the chucking member.

5. The substrate processing apparatus of claim 1, wherein the bonding protective member completely covers the outer side surface of the coating layer.

6. The substrate processing apparatus of claim 5, wherein the bonding protective member includes a metal oxide deposited on the outer side surface of the bonding layer by a deposition process.

7. The substrate processing apparatus of claim 1, wherein a vertical length of the coating layer is greater than a vertical length of the bonding layer.

8. The substrate processing apparatus of claim 1, further comprising:
a sealing member between the coating layer and the bonding protective member,
wherein a top portion and a bottom portion of the sealing member protrude toward the bonding protective member when viewed in a cross-sectional view perpendicular to a top surface of the chucking member.

9. The substrate processing apparatus of claim 8, wherein an outer side surface of the sealing member has a concave shape.

10. The substrate processing apparatus of claim 1, wherein the coating layer includes Al₂O₃, Y₂O₃, yttrium aluminum garnet (YAG), ZrO₂, TiO₂, or any combination thereof.

11. A substrate processing apparatus, comprising:
a chucking member configured to support a substrate by electrostatic force;
a base plate configured to support the chucking member;
a first bonding layer in contact with the chucking member and between the chucking member and the base plate;
a first coating layer on an outer side surface of the first bonding layer, the first coating layer conformally covering the outer side surface of the first bonding layer in a groove region defined by a bottom surface of the chucking member, a top surface of the base plate, and the outer side surface of the first bonding layer; and
a bonding protective member surrounding an outer side surface of the first coating layer,
wherein the base plate, the first bonding layer, and the chucking member include a pin hole extending in a vertical direction perpendicular to a top surface of the chucking member; and
a second coating layer conformally covers an inner wall of the pin hole.

12. The substrate processing apparatus of claim 11, wherein the second coating layer extends along the inner wall of the pin hole, and a portion of the second coating layer is in contact with the first bonding layer.

13. The substrate processing apparatus of claim 11, wherein a thickness of the first coating layer is greater than a thickness of the second coating layer.

14. The substrate processing apparatus of claim 11, wherein the bonding protective member is formed on the outer side surface of the first coating layer by a deposition process, and
the bonding protective member completely covers the outer side surface of the first coating layer.

15. The substrate processing apparatus of claim 11, further comprising:
a heating plate between the base plate and the chucking member; and
a second bonding layer between the heating plate and the base plate, the second bonding layer configured to adhere the heating plate to the base plate.

16. The substrate processing apparatus of claim 15, wherein the first coating layer is between the chucking member and the heating plate and is configured to adhere the chucking member to the heating plate.

17. The substrate processing apparatus of claim 15, wherein the first coating layer is in contact with
an outer side surface of the heating plate,
the outer side surface of the first bonding layer, and
an outer side surface of the second bonding layer.

18. The substrate processing apparatus of claim 15, wherein the second coating layer is in contact with
an inner side surface of the heating plate,
an inner side surface of the first bonding layer, and
an inner side surface of the second bonding layer.

19. A substrate processing apparatus, comprising:
a housing;
a shower head unit inside the housing, the shower head unit configured to supply a process gas for processing a substrate in the housing;
a substrate support unit installed under the shower head unit and configured to have the substrate seated thereon; and
a plasma generating unit configured to generate plasma by using the process gas to process the substrate,
wherein the substrate support unit includes
a chucking member configured to support the substrate by electrostatic force;
a base plate configured to support the chucking member;
a bonding layer between the chucking member and the base plate, the bonding layer configured to adhere the chucking member to the base plate;
a coating layer inside a groove region, the coating layer including a metal oxide formed on an outer side surface of the bonding layer by a deposition process, the groove region defined by a bottom surface of the chucking member, a top surface of the base plate, and an outer side surface of the bonding layer; and
a bonding protective member surrounding an outer side surface of the coating layer,
wherein the base plate, the bonding layer, and the chucking member include a pin hole extending in a vertical direction perpendicular to a top surface of the chucking member; and
a second coating layer conformally covers an inner wall of the pin hole, the second coating layer including a metal oxide formed by the deposition process.

20. The substrate processing apparatus of claim 19, wherein the deposition process includes at least one of chemical vapor deposition or atomic layer deposition.
